(19) United States
(12) Patent Application Publication
(10) Pub. No.: US 2026/0023128 A1
(43) Pub. Date: Jan. 22, 2026

(54) ENERGY STORAGE SYSTEM AND APPARATUS AND METHOD FOR MEASURING IMPEDANCE OF ENERGY STORAGE SYSTEM

(71) Applicant: SAMSUNG SDI CO., LTD., Yongin-si (KR)

(72) Inventor: SUK KI KIM, Yongin-si (KR)

(21) Appl. No.: 19/221,607

(22) Filed: May 29, 2025

(30) Foreign Application Priority Data
Jul. 19, 2024 (KR) 10-2024-0095861

(51) Int. Cl. G01R 31/389; G01R 31/3835

(52) U.S. Cl. CPC G01R 31/389; G01R 31/3835

(57) ABSTRACT

The present disclosure relates to an energy storage system including a rack formed of battery cells and a bank, and an apparatus and method for measuring impedance of the energy storage system. The energy storage system including racks each including a plurality of battery cells connected in series, a bank formed by connecting the racks in parallel, and an impedance meter configured to measure impedance of the bank or the racks. The impedance meter is configured to perform impedance measurement of the bank including all of the racks or each of the racks individually.

### CROSS-REFERENCE TO RELATED APPLICATION

This application claims priority to and the benefit of Korean Patent Application No. 10-2024-0095861, filed on Jul. 19, 2024, the disclosure of which is incorporated herein by reference in its entirety.

### BACKGROUND

### 1. Field of the Invention

The present disclosure relates to an energy storage system including a rack formed of battery cells and a bank, and an apparatus and method for measuring impedance in an energy storage system.

### 2. Discussion of Related Art

Unlike primary batteries that cannot be recharged, secondary batteries are batteries that can be charged and discharged. Low-capacity batteries are used in small portable electronic devices such as smartphones, feature phones, laptop computers, digital cameras, and camcorders. High-capacity batteries are widely used as driving power sources and power storage batteries for motors in hybrid vehicles, electric vehicles, and the like. Such batteries include an electrode assembly including a positive electrode and a negative electrode, a case for accommodating the electrode assembly, and an electrode terminal connected to the electrode assembly.

A plurality of batteries are assembled to form an energy storage system with increased voltage and/or current capacity. Categories of energy storage systems include battery modules/packs used in vehicles or electrical appliances. Impedance is measured to check whether an abnormality occurs in an energy storage system and monitor integrity of a system.

Conventionally, impedance has been measured by analyzing the characteristics of battery cells included in energy storage systems or modules/packs, and the internal impedance of individual cells has been measured to monitor and predict various states of the cells. Impedance measurement may be performed as part of electrochemical impedance spectroscopy (EIS) or as impedance measurement for independent purposes.

The information disclosed in this section is for enhancement of understanding of the background of the present disclosure and may contain information that does not constitute a related (or prior) art.

### SUMMARY OF THE INVENTION

The present disclosure is directed to an impedance measurement technique capable of monitoring not only a lifetime and an abnormality of an energy storage system but also an abnormality of an external interconnection by performing impedance measurement on bank including all of the racks or each of the racks.

According to one aspect of the present disclosure, there is provided an energy storage system including racks each including a plurality of battery cells connected in series, a bank formed by connecting the racks in parallel, and an impedance meter configured to measure impedance of the bank or the racks, wherein the impedance meter is configured to perform impedance measurement of the bank including all of the racks or each of the racks individually.

The impedance meter may be configured to measure impedance between two ends of the bank. The impedance meter may be configured to measure impedance between two ends of one or more of the racks.

The impedance meter may be configured to measure impedance between two ends of a sub-rack including some of the battery cells included in one or more of the racks.

According to another aspect of the present disclosure, there is provided an apparatus for measuring impedance of an energy storage system including racks each formed by connecting a plurality of battery cells in series, and a bank formed by connecting the racks in parallel. The apparatus may include a switching element that allows two ends of the racks to be connected to or disconnected from each other according to a waveform of an AC signal, and a detection resistor configured to detect a voltage generated according to the waveform of the AC signal.

The switching element may connect two ends of the bank. The switching element may connect two ends of one or more of the racks. The switching element may connect two ends of a sub-rack including some of the battery cells included in one or more of the racks.

According to still another aspect of the present disclosure, there is provided a method of measuring impedance of an energy storage system including racks each formed by connecting a plurality of battery cells connected in series, and a bank formed by connecting the plurality of racks connected in parallel. The method may include connecting a switching element that allows two ends of the racks to be connected to or disconnected from each other according to a waveform of an AC signal, and detecting a voltage generated according to the waveform of the AC signal.

The connection of the switching element may include connecting the switching element to two ends of one or more of the racks. The connection of the switching element may include connecting the switching element to two ends of a sub-rack including some of the battery cells included in one or more of the racks.

Aspects and features of the present disclosure are not limited to those described above, and other aspects and features not specifically mentioned herein will be clearly understood by those skilled in the art from the description of the present disclosure below.

### BRIEF DESCRIPTION OF THE DRAWINGS

The drawings attached to the present specification illustrate embodiments of the present disclosure and further describe aspects and features of the present disclosure together with the detailed description of the present disclosure. The present disclosure should not be construed as being limited to the drawings.

FIG. 1 schematically illustrates a pouch-type battery;

FIG. 2 is a cross-sectional view of a cylindrical battery;

FIG. 3A is a top perspective view OF an exterior of a prismatic battery;

FIG. 3B is a cross-sectional view along line I-I′ of FIG. 3A;

FIG. 4 is an exemplary view of a battery module in which batteries are arranged;

FIG. 5 is an exemplary view of a battery pack constructed to apply the battery module illustrated in FIG. 4 to an actual product;

FIG. 6 illustrates a schematic configuration of an energy storage system (ESS) according to some embodiments of the present disclosure;

FIG. 7 is a detailed configuration diagram of a bank of an ESS shown in FIG. 6;

FIG. 8 illustrates an embodiment of an ESS including the bank shown in FIG. 7;

FIG. 9 illustrates another embodiment of an ESS including the bank shown in FIG. 7;

FIG. 10 is a configuration diagram of a modified embodiment of the bank shown in FIG. 7;

FIG. 11 illustrates one embodiment of an ESS including the bank shown in FIG. 10;

FIG. 12A is an equivalent circuit of the bank and an impedance meter of FIG. 11;

FIG. 12B is an equivalent circuit in which the equivalent circuit of FIG. 12A is further simplified; and

FIG. 13 illustrates another embodiment of an ESS including the bank shown in FIG. 10.

### DETAILED DESCRIPTION OF EXEMPLARY EMBODIMENTS

Hereinafter, embodiments of the present disclosure will be described, in detail, with reference to the accompanying drawings. The terms or words used in the present specification and claims are not to be narrowly interpreted according to their general or dictionary meanings and should be interpreted as having meanings and concepts that are consistent with the technical idea of the present disclosure on the basis of the principle that an inventor can be his/her own lexicographer to appropriately define concepts of terms to describe his/her invention in the best way.

The embodiments described in this specification and the configurations shown in the drawings are only some embodiments of the present disclosure and do not represent all of the aspects, features, and embodiments of the present disclosure. Accordingly, it should be understood that there may be various equivalents and modifications that can replace or modify one or more embodiments or features therein described herein at the time of filing this application.

It will be understood that if an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, if a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” if describing embodiments of the present disclosure relates to “one or more embodiments of the present disclosure.” Expressions, such as “at least one of” and “any one of,” if preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” if used in this specification, specify the presence of stated features, integers, steps, operations, elements, and/or components but do not preclude the presence or addition of one or more other features, integers, steps, operations, elements, components, and/or groups thereof.

Numerical ranges disclosed and/or recited herein include all sub-ranges of the same numerical precision subsumed within the recited ranges. For example, a range of “1.0 to 10.0” is includes all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein includes all lower numerical limitations subsumed therein, and any minimum numerical limitation recited in this specification includes all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same.” Thus, the phrase “substantially the same” may include a case having a deviation that is considered low in the art, for example, a deviation of 5% or less. In addition, if a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may contact the upper (or lower) surface of the element, and another element may also be interposed between the element and the arbitrary element located on (or under) the element.

In addition, it will be understood that if a component is referred to as being “linked,” “coupled,” or “connected” to another component, the elements may be directly “coupled,” “linked” or “connected” to each other, or another component may be “interposed” between the components.”

Throughout the specification, if “A and/or B” is stated, it means A, B or A and B, unless otherwise stated. That is, “and/or” includes any or all combinations of a plurality of items enumerated. When “C to D” is stated, it means C or more and D or less, unless otherwise specified.

The terminology used herein is for the purpose of describing embodiments of the present disclosure and is not intended to limit the present disclosure.

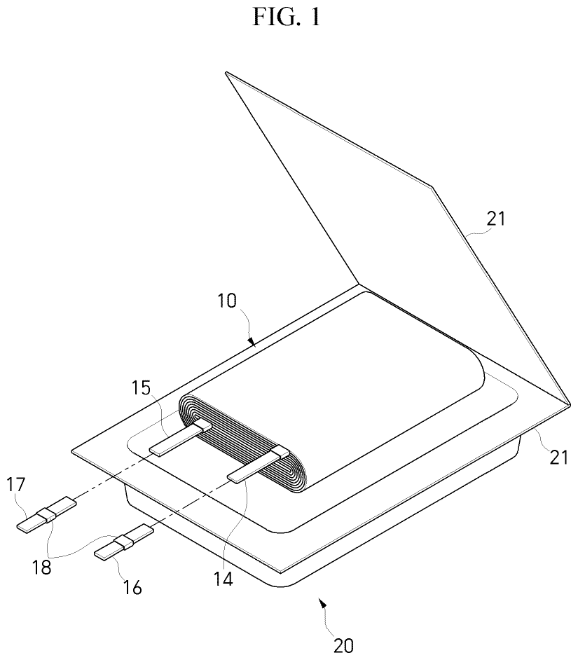

FIG. 1 schematically illustrates the pouch-type secondary battery. The pouch-type secondary battery includes an electrode assembly 10 and a pouch 20 that accommodates the electrode assembly 10.

The first electrode tab 14 and the second electrode tab 15 of the electrode assembly 10 may be electrically connected to respective external first and second terminal leads 16 and 17 by welding. Each of the first terminal lead 16 and the second terminal lead 17 may be attached with a tab film 18 for insulation from the pouch 20.

The pouch 20 may be sealed by having sealing parts 21 at the edges thereof contact each other with accommodating the electrode assembly 10 therein, in which case the sealing may be achieved with the tab film 18 interposed between the sealing parts 21. The sealing parts 21 of the pouch 20 may each be made of a thermal fusion material that has weak adhesion to metal. Thus, the pouch 20 may be sealed by interposing the thin tab film 18 between the sealing parts 21.

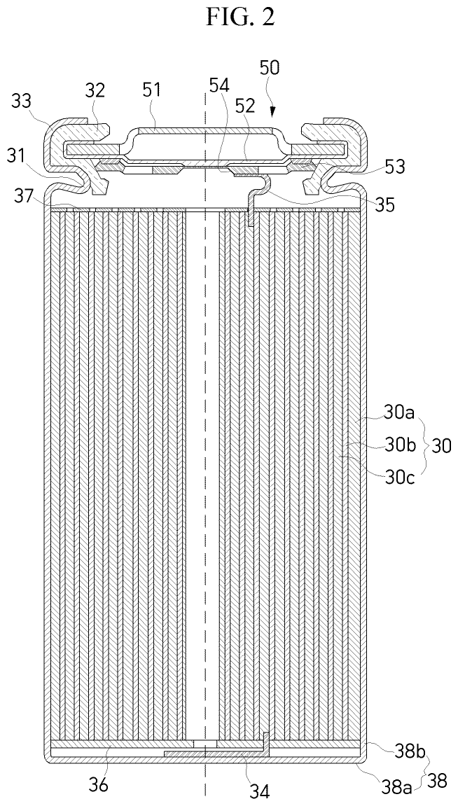

FIG. 2 illustrates a cylindrical secondary battery. The secondary battery includes an electrode assembly 30, a case 38 accommodating the electrode assembly 30 and an electrolyte therein, a cap assembly 50 coupled to an opening of the case 38 to seal the case, and an insulating plate 37 positioned between the electrode assembly 30 and the cap assembly 50 inside the case 38.

The electrode assembly 30 may include a separator 30b interposed between a first electrode 30c and a second electrode. The electrode assembly 30 may be wound in a jelly-roll shape.

The first electrode 30c includes a first substrate and a first active material layer on the first substrate. A first lead tab 35 may extend outwardly from a first uncoated portion of the first substrate at a position where the first active material layer is not provided, and the first lead tab 35 may be electrically connected to the cap assembly 50.

The second electrode 30a includes a second substrate and a second active material layer on the second substrate. A second lead tab 34 may extend outwardly from a second uncoated portion of the second substrate at a position where the second active material layer is not provided, and the second lead tab 34 may be electrically connected to the case 38. The first lead tab 35 and the second lead tab 34 may extend in opposite directions.

The first electrode 30c may act as a positive electrode. In such an embodiment, the first substrate may be made of, for example, an aluminum foil, and the first active material layer may include, for example, a transition metal oxide. The second electrode 30a may act as a negative electrode. In embodiments, the second substrate may be made of, for example, a copper foil or a nickel foil, and the second active material layer may include, for example, graphite.

The separator 30b prevents a short circuit between the first electrode 30c and the second electrode 30a while allowing movement of lithium ions therebetween. The separator 32b may be made of, for example, a polyethylene film, a polypropylene film, a polyethylene-polypropylene film, or the like.

The case 38 accommodates the electrode assembly 30 and, together with the cap assembly 50, forms the external appearance of the secondary battery. The case 38 may have a substantially cylindrical body portion 38b and a bottom portion 38a connected to one side (e.g., to one end) of the body portion 38b. A beading part 31 (e.g., a bead) deformed inwardly may be formed in the body portion 38b, and a crimping part 33 (e.g., a crimp) bent inwardly may be formed at an open end of the body portion 38b.

The beading part 31 can reduce or prevent movement of the electrode assembly 30 inside the case 38 and can facilitate seating of the gasket 32 and the cap assembly 50. The crimping part 33 may firmly fix the cap assembly 50 by pressing the edge of the case 38 against the gasket 32. The case 38 may be formed, for example, of iron plated with nickel.

The cap assembly 50 may be fixed to the inside of the crimping part by a gasket 32 to seal the case 38. The cap assembly 50 may include an upper cap 51, a safety vent 52, a lower cap 53, an insulating member, and a sub plate 54. But the present disclosure is not limited to such a configuration and may be modified in various ways.

The upper cap 51 may be positioned at the uppermost part of the cap assembly 50. The upper cap 51 may include a terminal part that protrudes upwardly and is connected to an external circuit. An outlet for discharging gas may be arranged around the terminal part.

The safety vent 52 may be located under the upper cap 51. The safety vent 52 may include a protrusion part that protrudes convexly downwardly and is connected to the sub plate 54. At least one notch may be formed in the safety vent 52 around the protrusion part.

When gas is generated due to overcharging or abnormal operation of the secondary battery, the protrusion part is deformed upwardly by the pressure and separates from the sub plate 54 while the safety vent 52 is opens (e.g., bursts or tears) along the notch. The opened safety vent 52 may prevent the secondary battery from exploding by allowing for the gas to be discharged to outside of the secondary batter.

The lower cap 53 may be positioned below the safety vent 52. The lower cap 53 may have a first opening for exposing the protrusion part of the safety vent 52 and a second opening for gas discharge. The insulating member may be positioned between the safety vent 52 and the lower cap 53 to insulate the safety vent 52 and the lower cap 53.

The sub plate 54 may be under the lower cap 53. The sub plate 54 may be fixed to a lower surface of the lower cap 53 to block the first opening of the cap down 53, and the protrusion part of the safety vent 52 may be fixed to the sub plate 54. The first lead tab 35, which is drawn out from the electrode assembly 30, may be fixed to the sub plate 54. Accordingly, the upper cap 51, the safety vent 52, the lower cap 53, and the sub plate 54 may be electrically connected to the first electrode 30c of the electrode assembly 30.

The insulating plate 37 may be positioned in contact with the electrode assembly 30 below the beading part 31. The insulating plate 37 may have a tab opening through which the first lead tab 35 is drawn out. The cap assembly 30, which is electrically connected to the first electrode 30c by the first lead tab 35, may face the electrode assembly 30 with an insulating plate 37 interposed therebetween. Thus, the cap assembly 30 may be insulated (e.g., electrically insulated) from the electrode assembly 30 by the insulating plate 37. Meanwhile, another insulating plate 36 may be included for insulation between the electrode assembly 30 and the bottom portion 38a of the case 38.

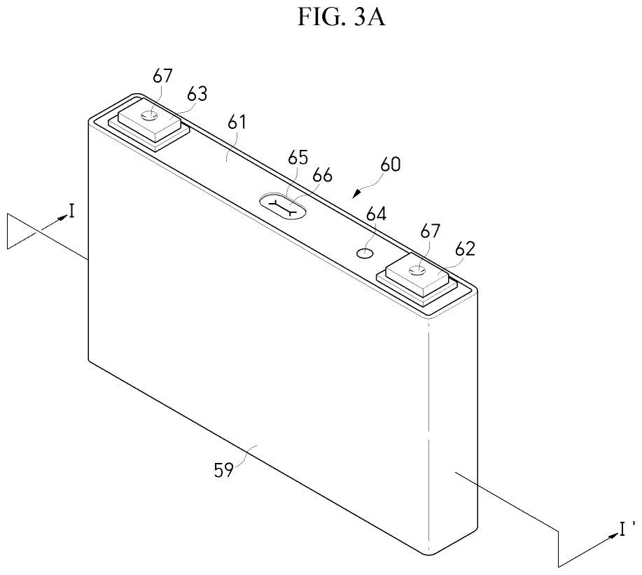

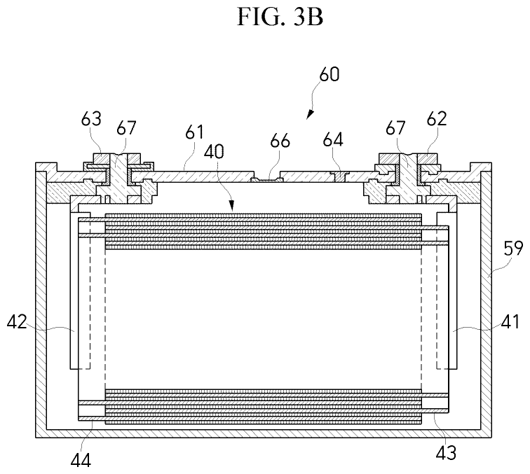

FIG. 3A is a top perspective view of a prismatic secondary battery.

A case 59 defines an overall appearance of the prismatic secondary battery. The case 59 may be made of a conductive metal, such as aluminum, aluminum alloy, or nickel-plated steel. In addition, the case 59 may provide a space for accommodating an electrode assembly therein.

A cap assembly 60 may include a cap plate 61 that covers the opening of the case 59. In some examples, the case 59 and the cap plate 61 may be made of a conductive material. Here, a first terminal 63 and a second terminal 62 may be electrically connected to respective positive and negative (or negative and positive) electrodes inside the case and may protrude outward through the cap plate 61.

The cap plate 61 may be equipped with an electrolyte injection port 64 that is sealed with a sealing plug (or seal pin). The cap plate 61 may also include a vent 66 formed with a notch 65. The vent 66 is for discharging gas generated inside the secondary battery.

FIG. 3B is a cross-sectional view taken along the line I-I′ of FIG. 3A, and illustrates an embodiment of the present disclosure.

As shown in FIG. 3B, a prismatic secondary battery may include an electrode assembly 40, a first current collector 41, a first terminal 62, a second current collector 42, a second terminal 63, a case 59, and a cap assembly 60.

An electrode assembly 40 may be formed by winding or stacking a stack of a first electrode plate, a separator, and a second electrode plate, which are formed as thin plates or films. When the electrode assembly 40 is a wound stack, a winding axis may be parallel to the longitudinal direction of the case 59. In some other embodiments, the electrode assembly 40 is a stack type rather than a winding type, and the shape of the electrode assembly 40 is not limited in the present disclosure. In addition, the electrode assembly 40 may be a Z-stack electrode assembly in which a positive electrode plate and a negative electrode plate are inserted into both sides of a separator, which is then bent into a Z-stack. In addition, one or more electrode assemblies may be stacked such that long sides of the electrode assemblies are adjacent to each other and accommodated in the case, and the number of electrode assemblies in the case is not limited in the present disclosure. The first electrode plate of the electrode assembly may act as a negative electrode, and the second electrode plate may act as a positive electrode. Of course, the reverse is also possible.

The first electrode plate may be formed by applying a first electrode active material, such as graphite, carbon, or the like, to a first electrode current collector that is formed of a metal foil, such as copper, a copper alloy, nickel, a nickel alloy, or the like. The first electrode plate may include a first electrode tab 43 (e.g., a first uncoated portion) that is a region to which the first electrode active material is not applied. The first electrode tab 43 may act as a current flow path between the first electrode plate and the first current collector 41. In some embodiments, when the first electrode plate is made, the first electrode tab 43 is cut to protrude to one side of the electrode assembly 40. In other embodiments, the first electrode tab 43 protrudes to one side of the electrode assembly 40 more than (e.g., farther than or beyond) the separator without.

The second electrode plate may be formed by applying a second electrode active material, such as a transition metal oxide, on a second electrode current collector formed of a metal foil, such as aluminum or an aluminum alloy. The second electrode plate may include a second electrode tab 44 (e.g., a second uncoated portion) that is a region to which the second electrode active material is not applied. The second electrode tab 44 may act as a current flow path between the second electrode plate and the second current collector 42. In some embodiments, the second electrode tab 44 may be cut in to protrude to the other side (e.g., the opposite side) of the electrode assembly when the second electrode plate is made. In other embodiments, the second electrode plate may protrude to the other side of the electrode assembly more than (e.g., farther than or beyond) the separator.

The separator prevents or substantially reduces instances of a short circuit between the first electrode and the second electrode while allowing movement of lithium ions therebetween. The separator may be made of, for example, a polyethylene film, a polypropylene film, a polyethylene-polypropylene film, or the like.

In some embodiments, the electrode assembly 40 is accommodated in the case 10 along with an electrolyte.

In the electrode assembly 40, the first current collector 41 and the second current collector 42 may be welded and connected to the first electrode tab 43 extending from the first electrode plate and the second electrode tab 44 extending from the second electrode plate, respectively. As described above, in some embodiments in which the first electrode tab 43 and the second electrode tab 44 are located at the top of the electrode assembly 40, the first and second current collectors are located at the top of the electrode assembly 40.

As illustrated in FIG. 3B, the first current collector 41 and the second current collector 42 are connected to the first terminal 62 and the second terminal 63 through connection members 67. In some embodiments, the connection members 67 may each have an outer peripheral surface that is threaded and may be fastened to the first terminal 62 and the second terminal 63 by screwing. However, the present disclosure is not limited thereto. For example, the connection members 67 may also be coupled to the first terminal 62 and the second terminal 63 by riveting or welding.

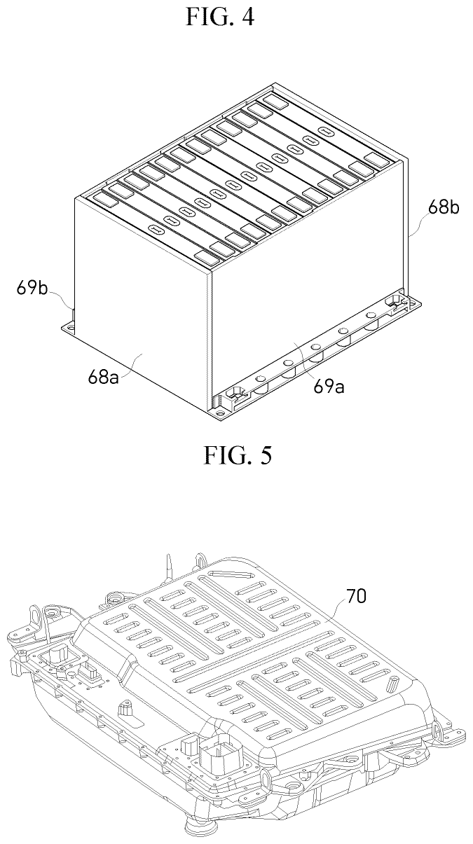

FIG. 4 is a perspective view of a secondary battery module in which secondary batteries are arranged according to embodiments of the present disclosure. With the increase in secondary battery capacity for driving electric vehicles, ESS (energy storage system) or the like, a secondary battery module may be manufactured by arranging a plurality of secondary battery cells transversely and/or longitudinally and connecting them together. The plurality of secondary batteries may be arranged in a space defined by a pair of facing end plates 68a and 68b and a pair of facing side plates 69a and 69b. The secondary batteries may be arranged in an arrangement (direction) and provided in a number to obtain desired voltage and current.

FIG. 5 is a perspective view of a battery pack 70 according to embodiments of the present disclosure. Referring to FIG. 5, the battery pack 70 may include an assembly to which individual batteries are electrically connected and a pack housing accommodating the same. In the drawings, for convenience components including a bus bar, a cooling unit, external terminals for electrically connecting batteries, etc., are not shown.

The secondary battery pack or ESS may include batteries and a battery management system (BMS) for managing the battery. The BMS uses sensors to and determine the voltage (V), current (I), and temperature (T) of batteries installed in electric vehicles or ESS. The BMS can thereby control the batteries so that they can perform optimally.

The battery management system may include a detection device, a balancing device, and a control device. The battery module may include a plurality of cells connected to each other in series and/or parallel. The battery modules may be connected to each other in series and/or in parallel.

The detection device may detect a state of a battery (e.g., voltage, current, temperature, etc.) to output information indicating the state of the battery. The detection device may detect the voltage of each cell constituting the battery or of each battery module. The detection device may detect current flowing through each battery module constituting the battery module or the battery pack. The detection device may also detect the temperature of a cell and/or module on at least one point of the battery and/or an ambient temperature.

The balancing device may perform a balancing operation of a battery module and/or cells constituting the battery module. The control device may receive state information (e.g., voltage, current, temperature, etc.) of the battery module from the detection device. The control device may monitor and calculate the state of the battery module (e.g., voltage, current, temperature, state of charge (SOC), life span (state of health (SOH)), etc.) on the basis of the state information received from the detection device. In addition, based on the monitored state information, the control device may perform a control function (e.g., temperature control, balancing control, charge/discharge control, etc.) and a protection function (e.g., over-discharge, over-charge, over-current protection, short circuit, fire extinguishing function, etc.). In addition, the control device may perform a wired or wireless communication function with an external device of the battery pack (e.g., a higher level controller or vehicle, charger, power conversion system, etc.).

The control device may control charging/discharging operation and protection operation of the battery. To this end, the control device may include a charge/discharge control unit, a balancing control unit, and/or a protection unit.

The BMS monitors the battery state and performs diagnosis and control, communication, and protection functions. The BMS may calculate the charge/discharge state, calculate battery life or state of health (SOH), cut off, as necessary, battery power (e.g., relay control), control thermal management (e.g., cooling, heating, etc.), perform a high-voltage interlock function, and may detect and/or calculate insulation and short circuit conditions.

A relay may be a mechanical contactor that is turned on and off by the magnetic force of a coil or a semiconductor switch, such as a metal oxide semiconductor field effect transistor (MOSFET).

The relay control has a function of cutting off the power supply from the battery if a problem occurs in the vehicle and the battery system and may include one or more relays and pre-charge relays at the positive terminal and the negative terminal, respectively.

In the pre-charge control, there is a risk of inrush current occurring in the high-voltage capacitor on the input side of the inverter when the battery load is connected. To prevent such an inrush current when starting a vehicle, the pre-charge relay may be operated before connecting the main relay and the pre-charge resistor may be connected. The high-voltage interlock is a circuit that uses a small signal to detect whether or not high-voltage parts of the vehicle system are connected and may function to forcibly open a relay if an opening occurs at even one location on the entire loop.

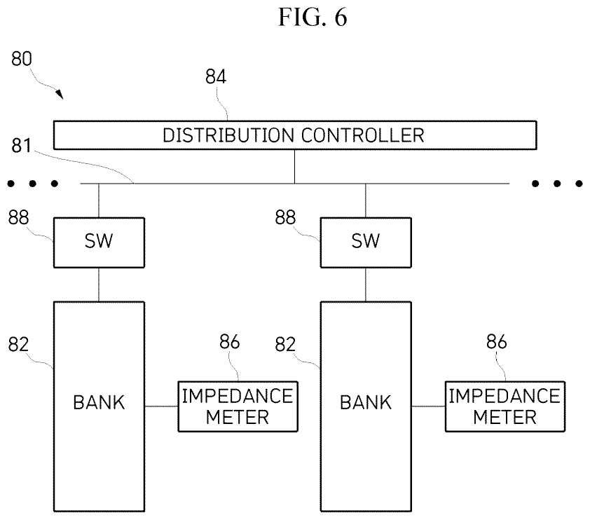

FIG. 6 illustrates a schematic configuration of an energy storage system (ESS) according to some embodiments of the present disclosure.

An ESS 80 may mainly include a plurality of banks 82 connected through busbars or harnesses 81 and a distribution controller 84 for distributing the banks 82.

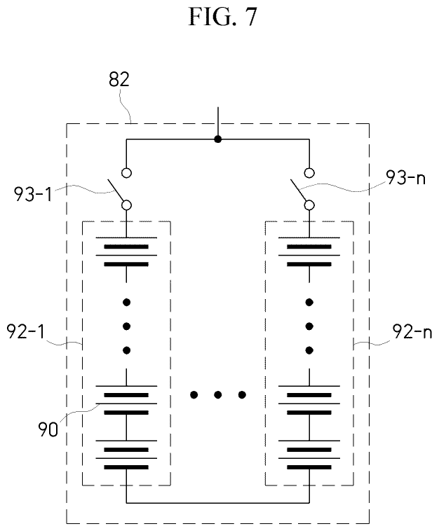

Each bank 82 is provided to have specific current capacity by connecting in parallel a plurality of racks. Each of the racks has a specific voltage by connecting a plurality of battery cells in series (see FIG. 7).

The distribution controller 84 may be configured to receive an instruction including a target charge/discharge amount of the bank 82 from a battery management system (BMS) or another control device, determine a priority of the bank 82 based on a state of charge (SOC) and a state of health (SOH) of each bank 82, select the bank 82 to be charged or discharged according to the target charge/discharge amount based on the priority, and charge or discharge the bank 82 according to the target charge/discharge amount and leave the remaining banks 82 of a battery idle. The distribution controller 84 may control switches 88 such that some banks are charged or discharged while other banks are left idle.

The BMS may provide information about an SOC and an SOH of the battery cells in the bank 82 to the distribution controller 84. In addition, the BMS may detect a voltage, current, and temperature of the battery cells (as described above) and determine an SOC and/or an SOH of the battery cells. In addition, the BMS may protect against overcharging, overdischarging, overcurrent, overvoltage, and overheating and perform cell balancing or the like.

In addition, in some embodiments of the present disclosure, one or more impedance meters 86 for measuring impedance of one or more of the banks 82 may be included. Here, impedance measurement may be performed as part of electrochemical impedance spectroscopy (EIS) or as impedance measurement for independent purposes.

Conventionally, battery impedance measurement (for example, EIS) has mostly been cell unit measurement in which various cell states are monitored and predicted by measuring internal impedance using a voltage of each cell to analyze characteristics of a battery cell. The impedance meter 86 of the present disclosure may perform impedance measurement in a unit of the bank 82 or rack (or a module) to observe not only a change in characteristics of a cell itself but also a change in impedance of peripheral circuits, busbars, harnesses, connectors, terminal blocks, and interconnections other than the cell. Therefore, the impedance meter 86 of the present disclosure enables the integrity of the entire ESS or battery pack to be monitored through impedance measurement in units of the banks or racks (or modules).

FIG. 7 is a detailed configuration diagram of the bank 82 of the ESS 80 shown in FIG. 6.

The bank 82 may be formed by connecting a plurality of racks 92-1 to 92-n in parallel. Each of the racks 92-1 to 92-n may be formed by connecting a plurality of battery cells 90 in series to obtain a desired voltage specification. For example, 200 battery cells with a voltage of 3.5 V may be connected in series to form a rack with a voltage of 700 V.

The bank 82 may be formed by connecting the plurality of racks 92-1 to 92-n in parallel to obtain a desired current. For example, 50 racks with a current capacity of 1 A may be connected in parallel to form a bank with a current capacity of 50 A.

Contactors 93-1 to 93-n, each of which is connected to one of the racks 92-1 to 92-n, may be included to activate/deactivate each of the racks 92-1 to 92-n in the bank 82. The contactors 93-1 to 93-n are mechanical switches that physically operate, electrical switches (for example, relays), semiconductor switches, or the like, and may be operated by a user or by a control signal.

In the present disclosure, the impedance meter 86 may measure impedance of the bank 82 or each of the racks 92-1 to 92-n. In order to select a measurement target rack from the racks 92-1 to 92-n and avoid interference of other racks, the contactors 93-1 to 93-n may be controlled to be turned on/off. In order to temporarily separate a rack of which impedance is to be measured, the contactor for the rack to be measured may be turned on, and the contactors for other racks may be turned off. When all of the contactors 93-1 to 93-n are turned on, the bank 82 including all of the racks 92-1 to 92-n connected in parallel may be a measurement target.

The bank 82 to be measured may be selected by turning the switch 88 shown in FIG. 6 on/off.

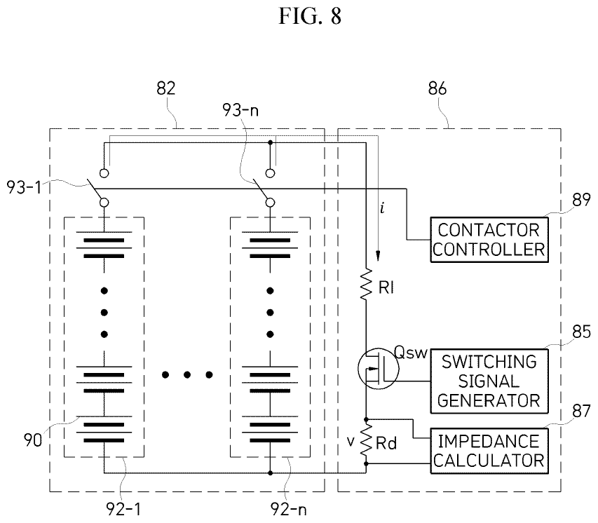

FIG. 8 illustrates one embodiment of an ESS 80 including the bank 82 according to the embodiment shown in FIG. 7.

The ESS 80 according to the present embodiment has a configuration in which one impedance meter 86 is connected to the bank 82. Accordingly, when all of contactors 93-1 to 93-n that allows racks 92-1 to 92-n to be connected to or disconnected from each other are turned on, impedance measurement is possible for all of the racks 92-1 to 92-n connected in parallel, (i.e., the whole bank 82). When a specific rack is selected with the contactors 93-1 to 93-n, impedance measurement of the selected rack may be measured.

An impedance meter 86 may include a switching element Qsw that allows two ends of a rack selected by the contactor 93-1 to 93-n to be connected to or disconnected from each other according to a predetermined waveform. for example, a positive terminal of a first cell and a negative terminal of a last cell among cells 90 constituting the rack in the present drawing. The switching element Qsw also allows a voltage charged in the constituent cells 90 of the rack to be discharged according to a predetermined waveform. The impedance meter may also include a load resistor Rl that limits a current i due to a discharge voltage of the constituent cells 90 of the racks 92-1 to 92-n and performs a voltage distribution function. A detection resistor Rd may be provided that detects the voltage v discharged according to the predetermined waveform from the constituent cells 90 by the switching element Qsw to calculate impedance of the racks 92-1 to 92-n. A switching signal generator 85 may be provided that generates a switching signal applied to a gate terminal of the switching element Qsw or a base terminal according to a type of the switching element. An impedance calculator 87 may be provided to calculates the impedance of the racks 92-1 to 92-n from a waveform of the voltage v appearing across two ends of the detection resistor Rd.

In the depicted configuration, when all of the contactors 93-1 to 93-n are turned on, impedance of two ends of all of the racks 92-1 to 92-n connected in parallel is measured. Thus, measured impedance value will be very low. Since impedance is low, it may be difficult to precisely analyze the bank 82. For more precise measurement, it is preferable that a specific rack is selected with a specific contactor to measure impedance of the selected rack.

A signal for switching the switching element Qsw may be generated in the switching signal generator 85. The switching signal may be a pulse wave, a regular sine wave, a triangle wave, a sawtooth wave, or the like. A frequency, period, rising/falling time, duration, slope, or the like of the switching element may change according to measurement conditions.

The impedance calculator 87 may calculate impedance by performing a Fourier transform (for example, a fast Fourier transformation (FFT)) on the waveform of the voltage v appearing across two ends of the detection resistor Rd. Methods in which a waveform of a battery voltage is detected using an AC signal to measure battery impedance, and performing a Fourier-transform on the waveform to calculate impedance is a well-known method.

In FIG. 8, the impedance meter 86 may additionally include a contactor controller 89 that controls turning-on/off of the contactors 93-1 to 93-n, but the present disclosure is not limited thereto. For example, the contactor controller 89 may be included in an element other than the impedance meter 86 such as a BMS. A user may directly manipulate the contactors 93-1 to 93-n to select a rack that is to be measured among the racks 92-1 to 92-n.

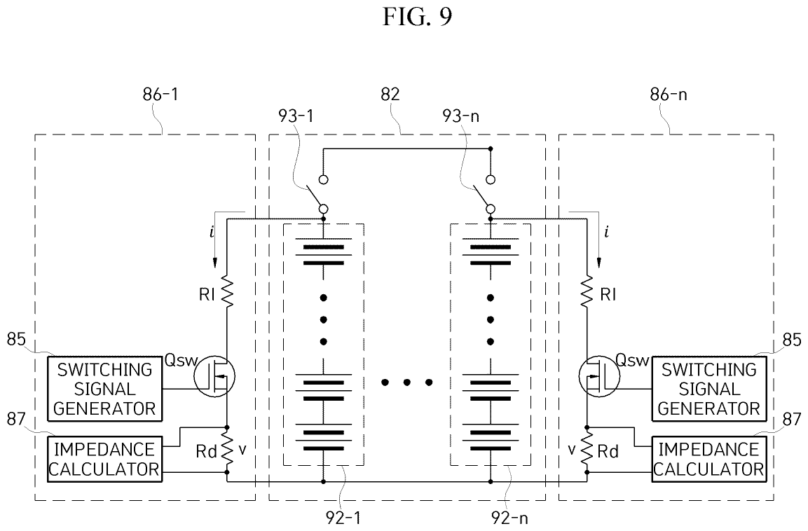

FIG. 9 illustrates another embodiment of an ESS 80 including the bank 82 shown in FIG. 7.

The ESS 80 according to the present embodiment has a configuration in which impedance meters 86-1 to 86-n are each assigned for each of one or more racks 92-1 to 92-n. The impedance meters may individually measure impedance of the assigned racks 92-1 to 92-n without needing to select a specific rack form the racks 92-1 to 92-n with contactors 93-1 to 93-n. Further, the impedance meters may perform the measurements at the same time.

The configuration of the impedance meters 86-1 to 86-n is substantially the same as that of the embodiment shown in FIG. 8. That is, the impedance meters 86-1 to 86-n may each include a switching element Qsw that allows two ends of each of the racks 92-1 to 92-n to be connected to or disconnected from each other according to a predetermined waveform and allows a voltage charged in constituent cells 90 of the racks 92-1 to 92-n to be discharged according to a predetermined waveform, a load resistor Rl that limits a current i due to a discharge voltage of the constituent cells 90 of the racks 92-1 to 92-n and performs a voltage distribution function, a detection resistor Rd that detects a voltage v discharged according to a predetermined waveform from the constituent cells 90 by the switching element Qsw to calculate impedance of the racks 92-1 to 92-n, a switching signal generator 85 that generates a switching signal applied to a gate terminal of the switching element Qsw (or a base terminal according to a type of the switching element), and an impedance calculator 87 that calculates the impedance of the racks 92-1 to 92-n from a waveform of the voltage v appearing across two ends of the detection resistor Rd.

In the case of the embodiment of FIG. 9, impedances of one or more racks 92-1 to 92-n may be quickly and simultaneously measured, which may be advantageous for real-time measurement for remote monitoring of an ESS. In addition, even in the case when all of the contactors 93-1 to 93-n are turned on and only one of a plurality of impedance meters 86-1 to 86-n is activated, impedance measurement is possible for all of the racks 92-1 to 92-n connected in parallel, that is, the impedance may be measured for the entire bank 82.

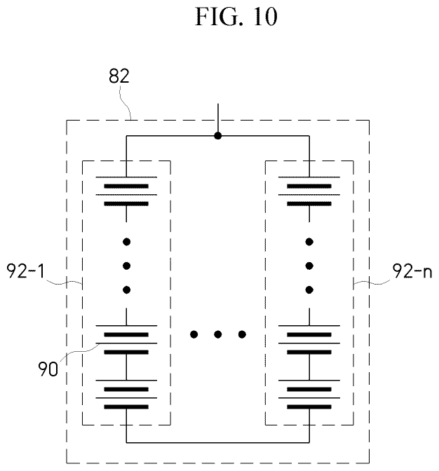

FIG. 10 illustrates a bank 82 according to an embodiment modified from the bank 82 shown in FIG. 7. Here, the bank 82 is also formed by connecting a plurality of racks 92-1 to 92-n in parallel, and each of the racks 92-1 to 92-n is formed by connecting a plurality of battery cells 90 in series. However, all of the racks 92-1 to 92-n are directly connected to each other without the contactors 93-1 to 93-n for selecting racks (as in the embodiment depicted in FIG. 7). In other words, the configuration of FIG. 10 may be equivalent to a state in which all of the contactors 93-1 to 93-n of the bank 82 of FIG. 7 are turned on. However, the absence of the contactors 93-1 to 93-n in the present embodiment means that there are no contactors for individually selecting target racks 92-1 to 92-n for impedance measurement. Nevertheless, with the configuration depicted in FIG. 10, other features such as specification changes or safety assurance are possible.

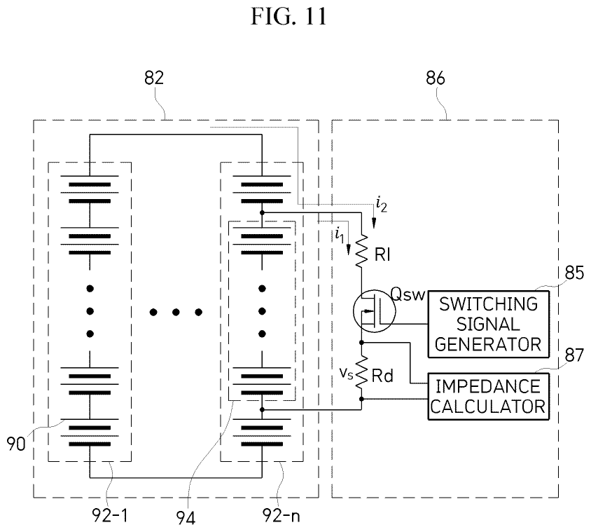

FIG. 11 illustrates an embodiment of an ESS 80 including the bank 82 shown in FIG. 10. The ESS 80 according to this embodiment is configured to enable impedance measurement for a specific desired rack without selecting a specific measurement target rack from racks 92-1 to 92-n.

To this end, unlike the above description, an impedance meter 86 is not connected to two ends of the racks 92-1 to 92-n (for example, in the present drawing, a positive terminal of a first cell and a negative terminal of a last cell among cells 90 constituting the rack) but is connected to two ends of a sub-rack 94 including some cells of battery cells included in a specific rack of the racks 92-1 to 92-n as shown in FIG. 11.

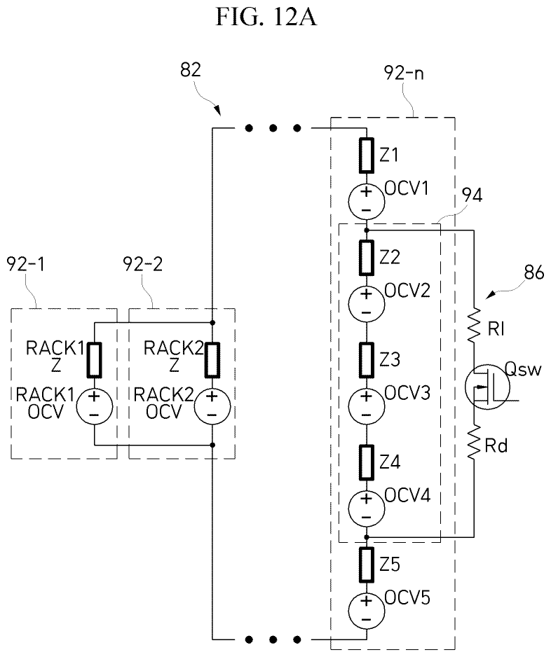

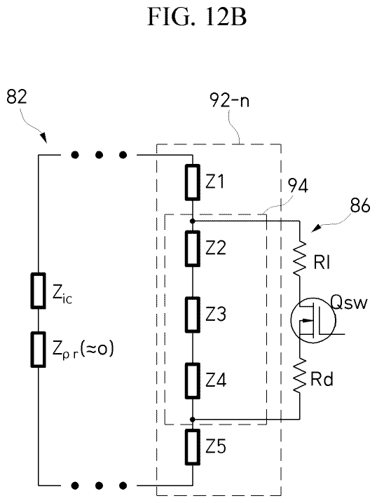

A current i₁ flowing due to a discharge voltage of the sub-rack 94 in one rack 92-n and a current i₂ flowing due to a discharge voltage of the remaining racks 92-1 to 92-(n−1) connected in parallel are superimposed to flow in a switching element Qsw of the impedance meter 86. Thus, a waveform of a voltage vₛ due to these two currents i₁ and i₂ appears across two ends of a detection resistor Rd. Therefore, an impedance value of the sub-rack 94 measured by the impedance meter 86 of FIG. 11 does not represent only impedance of the sub-rack 94. However, in an impedance measurement circuit of FIG. 11, because there is a large difference between the impedance of the sub-rack 94 and the impedances of the remaining racks 92-1 to 92-(n−1) connected in parallel (the latter being much lower than the former), from the perspective of the impedance meter 86, the impedance of the sub-rack 94 is significant and the impedances of the remaining racks 92-1 to 92-(n−1) connected in parallel may be ignored. Therefore, even without selecting a measurement target rack using a contactor, it is possible to measure impedance of a sub-rack including some cells of series-connected cells included in a specific rack. Such an impedance relationship is shown in FIGS. 12A and 12B.

FIG. 12A is an equivalent circuit of the bank 82 and the impedance meter 86 of FIG. 11. Since one rack may be equivalent to impedance Z and an open circuit voltage OCV, the bank 82 of FIG. 11 may be equivalent to a circuit in which the impedance Z and the open circuit voltage OCV of rack 1 92-1, the impedance Z and the open circuit voltage OCV of rack 2 92-2, and the impedances Z and the open circuit voltages OCV of rack 3 92-3, etc., and rack 92-n are connected in parallel. In addition, in one rack, the impedance Z and the open circuit voltage OCV of each cell are connected in series, and thus the one rack may be equivalent to a circuit in which Z1 and OCV1, Z2 and OCV2, Z3 and OCV3, 74 and OCV4, and Z5 and OCV5 are connected in series, wherein among these, Z2 and OCV2, Z3 and OCV3, and Z4 and OCV4 represent a sub-rack 94. Therefore, an equivalent circuit as shown FIG. 12A may be drawn. In FIG. 12A, Rl, Qsw, and Rd are connected to two ends of the sub-rack 94 to constitute an impedance meter 86.

FIG. 12B is an equivalent circuit from the perspective of pure impedance in which OCV as depicted in FIG. 12A is removed for easier understanding. In FIG. 12B, in addition to parallel impedance Zₚᵣ of rack 1, rack 2, . . . of a bank 82, impedance Z_{ic} of interconnections of harnesses or connectors is also shown. Here, the impedance Zpr of the parallel racks is close to zero because the impedance Zₚᵣ is obtained by connecting a plurality of impedances in parallel, and Z_{ic} is so small as to be ignored. Therefore, an impedance value measured by the impedance meter 86 is expressed using a parallel impedance value of the sum (Z1+Z2+Z3) of measured series impedances of a sub-rack 94 and the sum Z1+Z2 of series impedances outside the sub-rack 94. That is:

$$( Z 2 + Z 3 + Z 4 ) // ( Z 1 + Z 5 ) = \frac{( Z 2 + Z 3 + Z 4 ) ( Z 1 + Z 5 )}{( Z 1 + Z 2 + Z 3 + Z 4 + Z 5 )} .$$

Through such a principle, it is possible to measure impedance of a specific rack without selecting a measurement target rack in the circuit of FIG. 11.

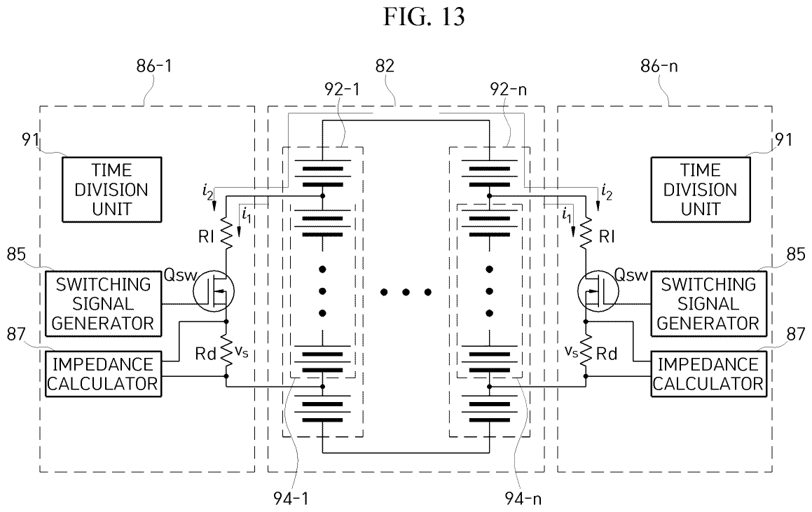

FIG. 13 illustrates another embodiment of an ESS 80 including the bank 82 shown in FIG. 10. The sub-racks 94-1 to 94-n described with reference to FIG. 11 may each be set for each of one or more racks 92-1 to 92-n, and impedance meters 86-1 to 86-n may each be added to one sub-rack. Therefore, in the ESS 80 according to the present embodiment, impedance measurement is possible for one or more racks. However, since impedance measurement times for a plurality of racks are not simultaneous, a time division unit 91 may be additionally included to divide a time of each impedance measurement and share the time. The time division unit 91 may be included in each of the impedance meters 86-1 to 86-n, but the present disclosure is not necessarily limited thereto. The time division unit 91 may be included in a BMS or other control devices.

According to the present disclosure, it is possible to monitor integrity of the entire battery system (ESS or battery module/pack) in a unit of a bank or rack. By observing impedance beyond simply monitoring a voltage, past impedance is compared with current impedance, thereby observing in real time whether an abnormality occurs in a unit of a bank or rack.

In addition, since it is possible to observe not only a change in characteristics of cells constituting an ESS but also a change in impedance of an interconnection, accidents caused by defects, failures, or degradation not only of cells but also of peripheral circuits, harnesses, connectors, or terminal block welded portions can be prevented.

Although the present disclosure has been described above with respect to embodiments thereof, the present disclosure is not limited thereto. Various modifications and variations can be made thereto by those skilled in the art within the spirit of the present disclosure.

What is claimed is:

1. An energy storage system comprising:
racks each including a plurality of battery cells connected in series;
a bank formed by connecting the racks in parallel; and
an impedance meter configured to measure impedance of the bank or the racks,
wherein the impedance meter is configured to perform impedance measurement of the bank including all of the racks or each of the racks individually.

2. The energy storage system as claimed in claim 1, further comprising contactors configured to electrically separate each of the of racks.

3. The energy storage system as claimed in claim 2, further comprising a contactor controller configured to control turning on and off of the contactors.

4. The energy storage system as claimed in claim 1, wherein the impedance meter comprises:
a switching element that allows two ends of the racks to be connected to or disconnected from each other according to a waveform of an AC signal; and
a detection resistor configured to detect a voltage generated according to the waveform of the AC signal.

5. The energy storage system as claimed in claim 4, wherein the impedance meter further comprises:
a switching signal generator configured to generate a switching signal applied to the switching element; and
an impedance calculator configured to calculate the impedance of the racks from a waveform of the voltage detected by the detection resistor.

6. The energy storage system as claimed in claim 1, wherein the impedance meter is configured to measure impedance between two ends of the bank.

7. The energy storage system as claimed in claim 1, wherein the impedance meter is configured to measure impedance between two ends of each of the racks.

8. The energy storage system as claimed in claim 1, wherein the impedance meter is configured to measure impedance between two ends of one or more sub-racks including some of the battery cells included in one or more of the racks.

9. The energy storage system as claimed in claim 8, further comprising a time division unit configured to allow an impedance measurement time for each rack to be shared when the impedance meter is configured to measure the impedance between the two ends of the one or more sub-racks.

10. An apparatus for measuring impedance of an energy storage system comprising racks each formed by connecting a plurality of battery cells in series and a bank formed by connecting the racks in parallel, the apparatus comprising:
a switching element that allows two ends of the racks to be connected to or disconnected from each other according to a waveform of an AC signal; and
a detection resistor configured to detect a voltage generated according to the waveform of the AC signal.

11. The apparatus as claimed in claim 10, further comprising:
a switching signal generator configured to generate a switching signal applied to the switching element; and
an impedance calculator configured to calculate impedance of the racks from a waveform of the voltage detected by the detection resistor.

12. The apparatus as claimed in claim 10, wherein the switching element connects two ends of the bank.

13. The apparatus as claimed in claim 10, wherein the switching element connects two ends of one or more of the racks.

14. The apparatus as claimed in claim 10, wherein the switching element connects two ends of one or more sub-racks including some of battery cells included in one or more of the racks.

15. The apparatus as claimed in claim 14, further comprising a time division unit configured to allow an impedance measurement time for each rack to be shared when the switching element connects two ends of the one or more sub-racks.

16. The apparatus as claimed in claim 10, wherein the energy storage system further comprises contactors configured to electrically separate each of the racks, and
wherein the apparatus further comprises a contactor controller configured to control turning on and off of the contactors.

17. A method of measuring impedance of an energy storage system comprising racks each formed by connecting a plurality of battery cells in series, and a bank formed by connecting the racks in parallel, the method comprising:
connecting a switching element that allows two ends of the racks to be connected to or disconnected from each other according to a waveform of an AC signal; and
detecting a voltage generated according to the waveform of the AC signal.

18. The method as claimed in claim 17, further comprising:
generating and applying a switching signal to the switching element; and
calculating impedance of the racks from a waveform of the voltage, which is detected by a detection resistor.

19. The method as claimed in claim 17, wherein the connecting of the switching clement comprises connecting the switching clement to the two ends of one or more of the racks.

20. The method as claimed in claim 17, wherein the connection of the switching element comprises connecting the switching clement to two ends of one or more sub-racks including some of the battery cells included in one or more of the racks.
